(19) United States
(12) Patent Application Publication
(10) Pub. No.: US 2025/0293721 A1
(43) Pub. Date: Sep. 18, 2025

(54) RECEIVER OF BEING CAPABLE OF ADAPTIVELY PROCESSING TRANSMISSION SIGNAL WITH VARIOUS FREQUENCY

(71) Applicant: LX SEMICON CO., LTD., Daejeon (KR)

(72) Inventors: Jeong Ho PARK, Daejeon (KR); Myung Yu KIM, Daejeon (KR)

(73) Assignee: LX SEMICON CO., LTD., Daejeon (KR)

(21) Appl. No.: 19/078,435

(22) Filed: Mar. 13, 2025

(30) Foreign Application Priority Data
Mar. 13, 2024 (KR) 10-2024-0035380

(51) Int. Cl. H04B 1/16; H03L 7/18; H04B 1/10

(52) U.S. Cl. CPC H04B 1/16; H03L 7/18; H04B 1/1018

(57) ABSTRACT

A receiver includes a filter for receiving and filtering an input signal from a host; a signal processing part configured to separate data components and frequency components from the filtered input signal; a frequency detector configured to receive the separated frequency components of the input signal and detect period information; a first clock generator configured to generate a clock for a signal to be transmitted to the host based on the detected period information of the input signal; and a controller configured to control the frequency detector and the first clock generator to read back the signal to the host.

### CROSS-REFERENCE TO RELATED APPLICATION

This application claims the priority of Korean Patent Application No. 10-2024-0035380, filed Mar. 13, 2024, which is hereby incorporated by reference in its entirety.

### BACKGROUND

### Field of the Disclosure

The present disclosure relates to a receiver capable of adaptively processing transmission signals of various frequencies and an operation method thereof.

### Description of the Background

The host may transmit data to the receiver by using signals in various frequency bands. Hence, the receiver may have to receive signals in various frequency bands of the host to obtain data.

In the related art, the transmission/reception frequency between the host and the receiver has been fixed by pre-agreement for advantage in data acquisition. However, in this case, when the frequency is fixed according to pre-agreement, there is a limitation because available frequency bands are limited.

Meanwhile, the receiver uses an oscillator to receive a signal from the host. Even when the transmission/reception frequency is fixed by agreement between the host and the receiver as described above, there may be a case where the frequency generated by the oscillator and the frequency fixed by agreement with the host do not match and a difference occurs due to the difference in the characteristics (+/−25%) of the oscillator itself actually used in the receiver.

Further, the difference that occurs in this way may eventually cause a problem in receiving signals transmitted from the host. That is, the difference such as the above may ultimately cause malfunction of the receiver.

In addition to the problem described above, with the advancement of digital technology, high-specification and high-performance application data is gradually increasing and transmission of signals containing such data is required. However, since the frequency band available between the host and the receiver is limited, there may be problems in that not only is the efficiency of signal transmission/reception reduced but also the required performance cannot be properly supported.

### SUMMARY

The present disclosure is to provide a method and device that supports receiving signals of various frequency bands of the host at the receiver.

The present disclosure is also to provide a method and device capable of preventing malfunction of the receiver in advance by considering oscillator characteristics in the receiver.

The present disclosure is not limited to those described in this section but includes those that may be understood through the description of the present disclosure.

A receiver according to at least one of various aspects of the present disclosure may include: a signal processing part configured to process an input signal of the host by using a first clock; a frequency detector configured to detect frequency information of the input signal of the host based on the first clock and a sampling clock of the signal processing part; and a controller configured to adaptively set a read back frequency of the receiver based on the detected frequency information of the input signal of the host.

In the above aspect, the receiver may further include a clock generator configured to generate a second clock for a signal to be transmitted to the host based on the adaptively set read back frequency of the receiver.

In the above aspect, the sampling clock may be faster than the first clock of the signal processing part.

In the above aspect, the controller may be configured to adaptively set the read back frequency in a manner that the ratio of a signal transmission frequency of the host and the read back frequency of the receiver is below a preset ratio.

In the above aspect, the controller may be configured to identify the type of the host.

In the above aspect, the receiver may further include an internal oscillator configured to generate a clock determined according to the identified type of the host and input the clock to the frequency detector.

In the above aspect, the internal oscillator may be configured to input the fastest clock frequency determined according to the identified type of the host to the frequency detector.

In the above aspect, if the clock input to the frequency detector is slower than the sampling clock of the signal processing part, the internal oscillator may be configured to newly generate a faster clock in sequence according to preset steps and input the same to the frequency detector.

In the above aspect, the receiver may further include a fixed clock value supplier configured to transfer a preset fixed clock value to the clock generator.

In the above aspect, the signal processing part may be configured to separate data components and frequency components from the input signal of the host by using the first clock.

According to at least one of the various aspects of the present disclosure, the receiver may receive signals of various frequency bands of the host, thereby supporting desired performance.

According to at least one of the various aspects of the present disclosure, malfunction due to an internal problem of the receiver may be prevented in advance, thereby ensuring stable operation of the receiver.

The technical effects of the aspects are not limited to those described in this section but include those that may be understood through the description of the present disclosure.

### BRIEF DESCRIPTION OF THE DRAWINGS

The above and other features and advantages of the present disclosure will become more apparent to those of ordinary skill in the art by describing exemplary aspects thereof in detail with reference to the attached drawings, in which:

FIG. 1 is a configuration diagram of a display device;

FIG. 2 illustrates a host and a receiver;

FIG. 3 is a block diagram illustrating a configuration of the receiver according to a first example;

FIG. 4 is a block diagram illustrating a configuration of the receiver according to a second example;

FIG. 5 is a flowchart illustrating a signal transmission method of the host;

FIGS. 6 to 9 are flowcharts illustrating a signal reception method of the receiver; and

FIG. 10 is a timing diagram illustrating a method for the receiver to detect signal transmission frequency information of the host.

### DETAILED DESCRIPTION

Hereinafter, with reference to the drawings, the present disclosure according to aspects to address the above problems will be described in greater detail.

The suffixes “module” and “part” for components as used in the following description are assigned solely for ease of drafting this specification and are not intended to confer any particular meaning or role. Therefore, the terms “module” and “part” may be used interchangeably.

Terms containing ordinal numbers, such as first, second, and the like, may be used to describe different components, but the components are not limited by such terms. These terms are used for the sole purpose of distinguishing one component from another.

Singular expressions include plural expressions unless the context clearly indicates otherwise.

In the present application, the terms such as “have”, “comprise”, or “include” are intended to indicate the presence of features, figures, steps, actions, components, parts, or any combination thereof described in the specification, but do not preclude the presence of or the possibility of the addition of one or more other features, figures, steps, actions, components, parts, or any combination thereof.

The host may transmit signals containing data to the receiver at different frequencies. In this case, the present specification seeks to preempt in advance any concerns about malfunction by reading back frequencies corresponding to various frequencies of the host from the receiver through various aspects of the present disclosure.

Hereinafter, a description will be given of a method and device for the receiver to read back a frequency corresponding to various frequencies of the host according to the present disclosure.

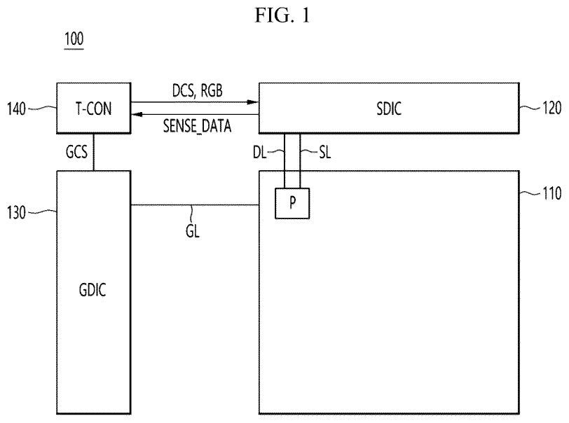

FIG. 1 is a configuration diagram of a display device 100 according to an aspect of the present disclosure.

With reference to FIG. 1, the display device 100 may include a display panel 110, a source driver 120, a gate driver 130, a timing controller (T-con) 140, and the like.

On the display panel 110, a plurality of data lines DL, a plurality of gate lines GL, and a plurality of sensing lines SL may be arranged, and a plurality of pixels P may also be arranged.

The gate driver 130 may supply a scan signal of a turn-on voltage or a turn-off voltage to the gate line GL. When a scan signal of a turn-on voltage is supplied to a pixel P, the pixel P is connected to the data line DL, and when a scan signal of a turn-off voltage is supplied to a pixel P, the connection between the pixel P and the data line DL is released.

The source driver 120 supplies a data voltage to the data line DL. The data voltage supplied to the data line DL is delivered to the pixel P connected to the data line DL according to the scan signal.

The source driver 120 may be referred to as a data driving circuit or a source driver integrated circuit (SDIC).

The source driver 120 may sense the characteristic value formed in each pixel P, for example, voltage, current. The source driver 120 may be connected to each pixel P by the scan line, or may be connected to each pixel P by a separate sensing line. At this time, the sensing signal may be generated by the gate driver 130.

The timing controller 140 may supply various control signals to the gate driver 130 and the source driver 120. The timing controller 140 may generate a gate control signal (GCS) for initiating scanning according to the timing implemented in each frame and forward it to the gate driver 130.

Additionally, the timing controller 140 may output image data RGB, converted from image data input from the outside into a data signal format used by the source driver 120, to the source driver 120.

Further, the timing controller 140 may transmit a data control signal (DCS) that controls the source driver 120 to supply data voltage to each pixel P according to each timing.

The timing controller 140 may transmit image data R/G/B that is compensated according to the characteristics of the pixel P.

The timing controller 140 may control the power management IC (PMIC) to supply a voltage to the panel.

The display panel 110 may be, but not limited to, an organic light-emitting display panel. For example, pixels P arranged on the display panel 110 may include an organic light-emitting diode (OLED) and one or more transistors.

The characteristics of the organic light-emitting diode (OLED) and transistor included in each pixel P may change depending on time or the surrounding environment, and the source driver 120 may sense the characteristics of these elements included in each pixel P and transfer the same to the timing controller 140.

The source driver 120 may be included in one integrated circuit. Additionally, the source driver 120 and the timing controller 140 may be included in a single integrated circuit, which may be referred to as an integrated IC.

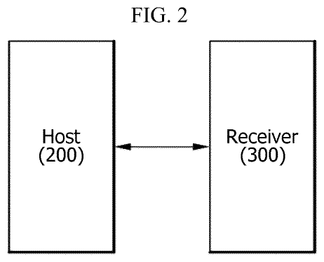

FIG. 2 illustrates a host 200 and a receiver 300 according to an aspect of the present disclosure.

Basically, in the present disclosure, the host 200 and the receiver 300 may be defined from the perspective of the entities transmitting and receiving data. For example, the host 200 may represent an entity (i.e., component) that transmits data, and the receiver 300 may represent an entity that receives data, on the contrary. In this process, the host 200 may transmit a signal containing data to the receiver 300 through various frequency bands.

According to an aspect, both the host 200 and the receiver 300 may be internal components of the display device 100. Hence, the host 200 transmits data to the receiver 300, and the receiver 300 receives the data transmitted from the host 200. Meanwhile, the receiver 300 may process the received data and transfer it to the display panel 110 for output.

In addition, the receiver 300 may transmit a signal to the host 200. Further, the receiver 300 may transmit a signal to another receiver (not shown).

In other words, the host 200 may function as a host in its relationship with the receiver 300, but may also function as a receiver in its relationship with other components. Likewise, the receiver 300 may function as a receiver in its relationship with the host 200, but may also function as a host in its relationship with other components.

According to another aspect, the host 200 may be an external device that transmits a signal containing data. If the host 200 is an external device, the receiver 300 may be a display device 100.

In the present disclosure below, for convenience of explanation, both the host 200 and the receiver 300 are described as internal components of the display device 100, i.e., specific components. However, the present disclosure is not limited thereto.

Referring to FIGS. 1 and 2, the host 200 may be the timing controller (T-con) 140 of the display device 100, and the receiver 300 may be the driver IC that receives data from the timing controller (T-con) 140.

Meanwhile, the timing controller (T-con) 140 may not only always transmit data to other components within the display device 100, but may also receive data. Hence, the timing controller (T-con) 140 may be not limited to the role of the host 200, but may also play the role of the receiver 300. In this sense, the receiver 300 in FIG. 2 may include the above-described timing controller (T-con), driver IC, GPU (graphics processing unit), or the like.

In particular, the host 200 illustrated in FIG. 2 is described as the timing controller (T-con), and the receiver 300 is described as the driver IC. However, the present disclosure is not limited thereto.

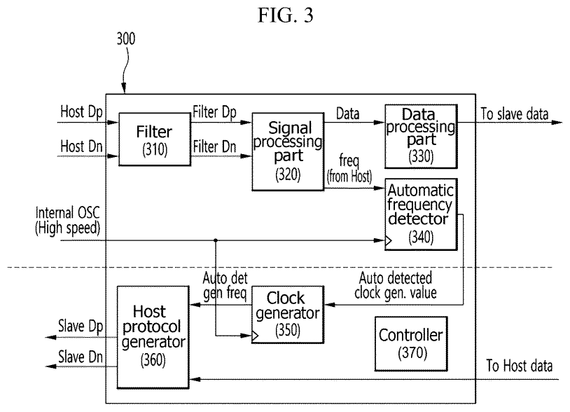

FIG. 3 is a block diagram of the receiver 300 according to an aspect of the present disclosure.

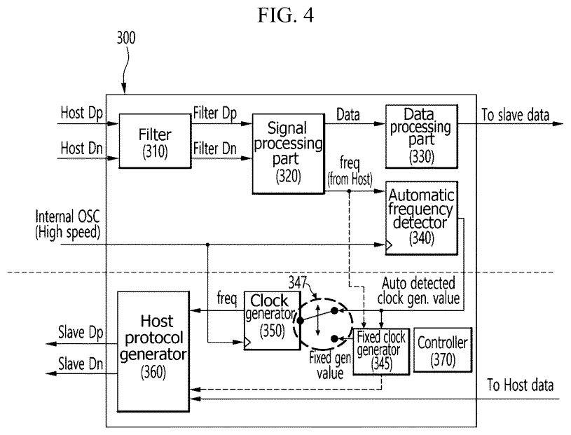

FIG. 4 is a block diagram of the receiver 300 according to another aspect of the present disclosure.

Referring to FIG. 3, the receiver 300 may be largely divided into a part (first part) (upper part of the dotted line in FIG. 3) that processes data received from the host 200 and a part (second part) (lower part of the dotted line in FIG. 3) that processes data to be transmitted to the host.

Meanwhile, the controller 370 being one of the components of the receiver 300 is depicted as belonging to the second part, i.e., the lower part of the dotted line, but it may be not limited to belonging to a specific part in that the controller 370 controls the overall operation of the receiver 300. The same may also apply to the internal oscillator (internal OSC) shown in FIG. 3.

The first part may include a filter 310, a signal processing part 320, a data processing part 330, an automatic frequency detector 340, and the like. The first part may be viewed as a data reception part.

The second part may include a clock generator 350, a host protocol generator 360, and the like. The second part may be viewed as a data transmission part.

The above-described part concepts are specifically divided for convenience of explanation without being limited thereto. For example, the above parts may be independent configurations in the receiver 300, or may be configurations linked to each other.

According to an aspect of the present disclosure, although the first part and the second part are responsible respectively for receiving data and transmitting data, they are interconnected with each other through the automatic frequency detector 340 in the first part, so that the second part may read back a signal by utilizing information of the first part.

First, the first part that receives and processes a signal containing data from the host 200 will be described.

In the first part, serial data information may be obtained from a signal received from the host 200.

At this time, the reception signal may include Host Dp (positive) and Host Dn (negative) information. However, Host Dp and Host Dn are information that may be obtained in the case of USB type-C, and the present disclosure may be not limited thereto.

Depending upon the aspect, instead of receiving Host Dp and Host Dn signals through two data lines as shown in FIG. 3, the receiver 300 may receive only one signal through one data line. 3. This may be defined differently depending on the type of the host 200 and/or the receiver 300.

The filter 310 may receive transmission signals Host Dp and Host Dn from the host 200.

The filter 310 may filter out noise from the received signals Host Dp and Host Dn. The filtered signals Filter_Dp and Filter_Dn may be transferred to the signal processing part 320.

In the above, the transmission signal of the host 200 input to the filter 310 may be an analog signal.

Meanwhile, the filter 310 may be not an essential component. Therefore, depending on the aspect, the filter 310 may be omitted or disposed at another location of the receiver 300 or the display device 100.

The signal processing part 320 may separate data components and frequency components from the input signal (e.g., signal filtered by the filter 310).

The data components separated in this way may be transferred to the data processing part 330.

On the other hand, the separated frequency components may be transferred to the automatic frequency detector 340.

The signal processing part 320 may be, for example, clock and data recovery (CDR).

The signal processing part 320 may restore a first clock through a clock training and restore data from the input signal of the host 200 based on the first clock. The signal processing part 320 may include a phase locked loop (PLL) or a delay locked loop (DLL). However, the present disclosure is not limited thereto.

The data processing part 330 may perform operations such as process or store on data components that are input separately from the signal processing part 320. The data processed in this way may be transferred to a slave, i.e., another component within the display device 100. Here, the other component may include the display panel 110.

The automatic frequency detector 340 may detect information (e.g., period information) about the frequency used by the host for signal transmission from frequency components that are input separately from the signal processing part 320.

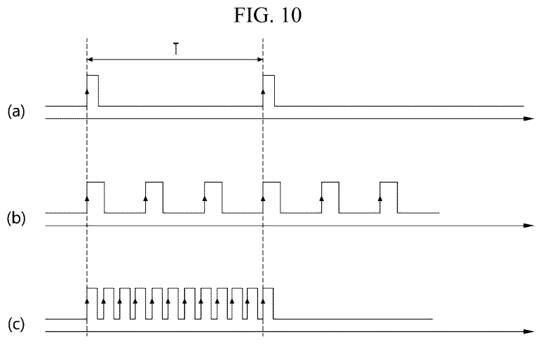

For example, FIG. 10 is a timing diagram illustrating an example of a method for the receiver 300 to detect signal transmission frequency information of the host 200.

For example, the automatic frequency detector 340 may utilize the following methods to detect information about the signal transmission frequency of the host. However, the present disclosure is not limited thereto.

One method is to obtain periodic information of the separated input signal of the host 200 by using a sampling frequency preset in the automatic frequency detector 340.

In relation to this, part (a) of FIG. 10 illustrates an input signal of the host 200, and part (b) of FIG. 10 illustrates a sampling frequency used in the automatic frequency detector 340.

The automatic frequency detector 340 may obtain period information by using a preset sampling frequency for the input signal of the host 200. For example, it may calculate the number of clocks according to the sampling frequency for one period of the input signal of the host 200 and obtain period information of the input signal of the host 200 based on the calculated number of clocks. The automatic frequency detector 340 may obtain period information of the input signal by comparing the first clock restored by the signal processing part 320 with the sampling frequency.

Another method is to receive a reference clock in the automatic frequency detector 340 and obtain period information of the separated input signal of the host 200 by using the received reference clock.

As described above, part (a) of FIG. 10 illustrates an input signal of the host 200, and part (c) of FIG. 10 illustrates a reference clock received in the automatic frequency detector 340.

In a similar manner, the number of reference clocks for one period of the input signal of the host 200 may be calculated, and period information of the input signal of the host 200 may be obtained based on the calculated number of reference clocks.

In utilizing the sampling frequency or reference clock illustrated to obtain period information of the input signal of the host 200 described above, neither the sampling frequency nor the reference clock may be always fixed values. In an aspect, a sampling clock may mean the sampling frequency or may mean the reference clock. Alternatively, the sampling clock may be a concept that includes both the sampling frequency and the reference clock.

For example, the controller 370 may identify the type of the host 200 in communication with the receiver 300, and the aforementioned sampling frequency and reference clock may be determined or changed according to the type of the host 200 identified by the controller 370.

The memory (not shown) may store information about a pre-stored appropriate sampling frequency or reference clock depending on the type of the host 200.

The controller 370 may control utilizing a reference clock having a clock speed faster than the fastest frequency among the frequencies available to the identified type of the host 200.

The controller 370 may control transmitting a first reference clock having a first clock speed.

If the period information for the input signal of the host 200 is not detected in the automatic frequency detector 340 based on the first reference clock, the controller 370 may control transmitting a second reference clock having a second clock speed. At this time, the second clock speed may be a clock speed that is faster than the first clock speed.

Meanwhile, the above-described operations may be repeated, for example, n times (where n is a natural number).

After repeating n times, if failing to detect the period information for the input signal of the host 200 even by using an n^{th} reference clock having an n^{th} clock speed, the controller 370 may obtain the period information for the input signal of the host 200 by using a reference clock having the fastest clock speed that may be generated in the receiver 300.

Nevertheless, if the period information is not detected, all settings of the automatic frequency detector 340 may be reset and the above-described process may be performed again in sequence.

Meanwhile, the controller 370 may control performing both of the period information acquisition methods described above.

According to the aspect, the controller 370 may control performing one of the two aforementioned period information acquisition methods first and, if the reliability of the performance result is below a preset threshold, control performing the remaining method additionally.

The receiver 300 may determine that the reliability is low if the sampling frequency or reference clock is not appropriate for detecting or obtaining period information (e.g., outside the expected value), even though it is based on information about the appropriate sampling frequency or reference clock stored in the memory (not shown) depending on the type of the host 200.

As described above, the automatic frequency detector 340 detects the period information of the host 200 by using a reference clock, and the reference clock for this purpose may be directly generated (not shown) or received from the outside. In the latter case, the reference clock may be generated by an internal oscillator (internal OSC) shown in FIG. 3 or 4 and be input to the automatic frequency detector 340.

Next, the receiver 300 may obtain data to be transmitted to the host 200. Here, a description is given of the second part in which the receiver 300 transmits a signal by utilizing the transmission frequency information (period information) for signal transmission of the host 200 automatically detected in the first part described above.

The frequency information automatically detected by the automatic frequency detector 340 may be input to the clock generator 350. The clock generator 350 may generate a frequency clock based on the input frequency. The frequency clock generated in this way may be input to the host protocol generator 360. The generated frequency clock may be defined as a second clock.

The host protocol generator 360 may generate a signal that conforms to the host protocol based on the input host data and the frequency clock input from the clock generator 350. The signal (Slave Dp, Slave Dn) generated in this way may be output to the host 200.

Next, FIG. 4 illustrates a configuration block diagram of the receiver 300 according to another aspect. Here, the receiver 300 shown in FIG. 4 may further include a fixed clock generator 345 and a switch in comparison to the configuration block diagram of the receiver shown in FIG. 3.

Both the clock generator 345 and the switch may correspond to the configuration of the second part described above.

Meanwhile, for the description of the components of the receiver 300 shown in FIG. 4 that are identical to those components in FIG. 3 described above, refer to the above-mentioned content, and repeated descriptions thereof are omitted. Hence, only the parts that are different from those of FIG. 3 are described below.

As described above, the signal processing part 320 may obtain data components and frequency components of the transmission signal from the signal transmitted from the host 200. The signal processing part 320 may operate as follows based on the transmission frequency information of the host 200 extracted from the frequency components of the transmission signal.

The signal processing part 320 may directly determine whether the signal transmission frequency of the host corresponds to a preset frequency, and if the signal transmission frequency of the host 200 corresponds to the preset frequency, unlike FIG. 3 described above, the signal transmission frequency information of the host 200 may be directly transferred to the fixed clock generator 345 while bypassing the automatic frequency detector 340. However, even in this case, the signal processing part 320 may transfer the signal transmission frequency information of the host 200 to the fixed clock generator 345 by use of the automatic frequency detector 340.

However, if the signal processing part 320 determines that the signal transmission frequency of the host 200 does not correspond to the preset frequency, the signal transmission frequency information of the host 200 may be transferred to the clock generator 350 via the automatic frequency detector 340, as described in FIG. 3.

When receiving signal transmission frequency information of the host 200 from the signal processing part 320 or the automatic frequency detector 340, the fixed clock generator 345 may generate a clock having a corresponding frequency based on the signal transmission frequency information of the host 200 and transfer the clock to the host protocol generator 360 via the clock generator 350 or directly transfer the clock to the host protocol generator 360.

Meanwhile, the switch 347 may be controlled by at least one of the controller 370, the signal processing part 320, and the automatic frequency detector 340.

In the above process, the switch 347 being connected by default to the automatic frequency detector 340 may release the connection under the control of at least one of the controller 370, the signal processing part 320, and the automatic frequency detector 340. At this time, when the connection is released, the switch 347 may be connected to the fixed clock generator 345.

However, the switch 347 is not an essential component, and may be unnecessary if the fixed clock generator 345 is directly connected to the host protocol generator 360.

Meanwhile, in the above, when the clock is generated from the fixed clock generator 345 in active state and the clock is transferred to the clock generator 350 through the switch 347, the clock generator 350 may transfer the clock received from the fixed clock generator 345 to the host protocol generator 360 as is without generating a separate clock.

Meanwhile, in the above, the preset frequency may be, for example, a frequency agreed upon in advance between the host 200 and the receiver 300. This pre-agreed frequency may be a fixed frequency value in relation to the host 200. In other words, the preset frequency may vary depending on the host. Alternatively, the pre-agreed frequency may be one of multiple fixed frequencies in relation to the host 200.

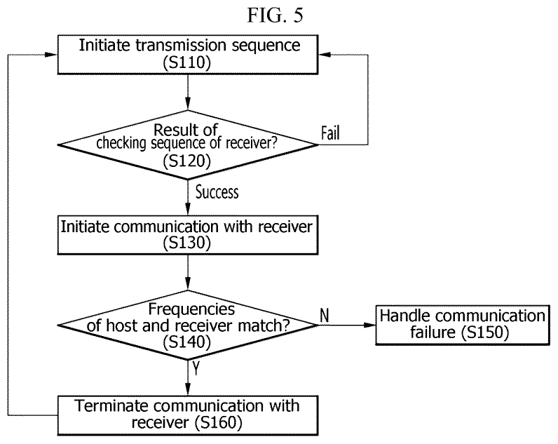

FIG. 5 describes a signal transmission method of the host 200.

The host 200 may initiate a transmission sequence to the receiver 300 (S110).

The host 200 may receive the result of checking the sequence from the receiver 300 in response to operation S110 and check whether it is successful (S120).

If the sequence check in the receiver 300 is not determined to be successful as the result of operation S120, i.e., if the sequence fails, the host 200 may change the frequency and perform operations S110 to S120 again, i.e., restart the sequence.

On the other hand, if the sequence check in the receiver 300 is determined to be successful as the result of operation S120, the host 200 may initiate communication with the corresponding receiver 300 (S130).

The host 200 may determine whether the frequencies of the host and the receiver match (S140).

If the frequencies of the host and the receiver do not match as the result of operation S140, the host 200 may determine that communication between the two ends has failed (S150).

On the other hand, if the frequencies of the host and the receiver match as the result of operation S140, the host 200 may determine that communication is occurring smoothly between the two ends, and may later normally terminate the communication with the receiver 300 (S160).

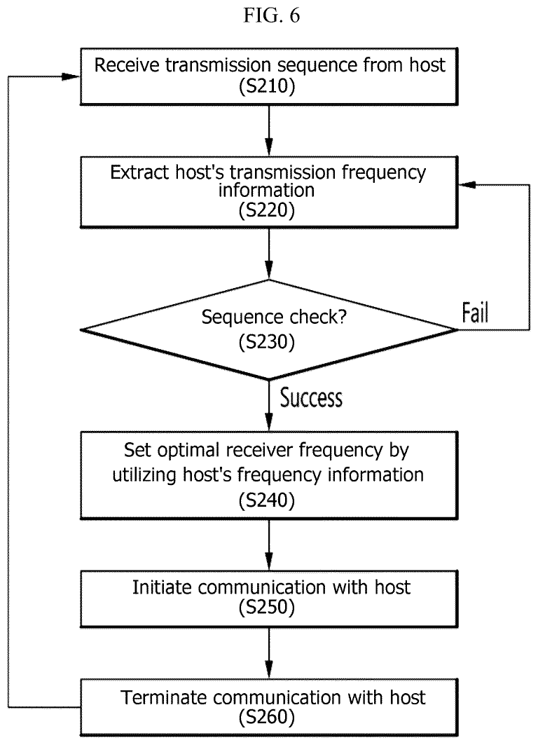

Next, FIGS. 6 to 9 describe a signal reception method of the receiver 300. At this time, the configuration of the receiver 300 may be, for example, the same as in FIG. 3 or FIG. 4.

First, a description is given of an example of the signal reception method of the receiver 300 with reference to FIG. 6.

The receiver 300 may receive a transmission sequence from the host 200 (S210).

The receiver 300 may extract transmission frequency information of the host 200 based on the transmission sequence received according to operation S210 (S220).

The receiver 300 may determine whether the sequence check is successful according to operation S220 (S230).

If the sequence check result is determined to be unsuccessful at operation S230, i.e., if determined as failure, the receiver 300 may return to operation S210 and may receive the sequence transmitted by the host 200 again.

Meanwhile, in this case, the receiver 300 may report or return a sequence failure to the host 200.

On the other hand, if the sequence check result is determined to be successful at operation S230, the receiver 300 may set an optimal receiver frequency based on the transmission frequency information of the host 200 extracted at operation S220 (S240).

The receiver 300 may initiate communication with the host according to the frequency set at operation S240 (S250), and may later end the communication (S260).

After operation S260, since there may be an event such as retransmission from the host 200, the receiver 300 may wait in a state in which it may receive a transmission sequence from the host 200 again in preparation for such an event. That is, the receiver 300 may return to operation S210 after operation S260 and may remain in a standby state.

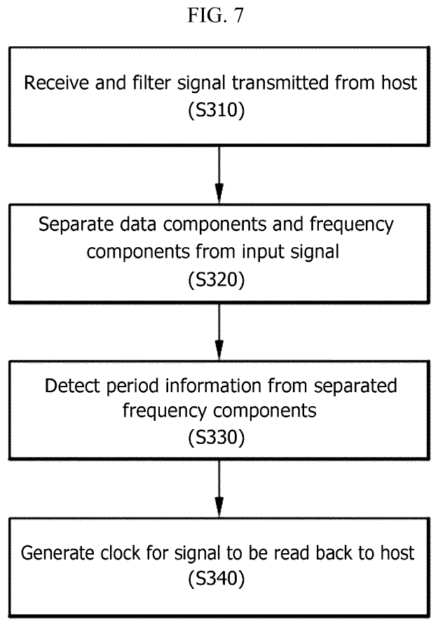

Next, referring to FIG. 7, the receiver 300 may receive a signal transmitted from the host 200 and filter the received signal (S310).

The receiver 300 may separate data components and frequency components from the filtered input signal (S320).

The receiver 300 may detect transmission frequency information, i.e., period information, of the host 200 based on the separated frequency components (S330).

The receiver 300 may generate a clock for a signal to be read back to the host 200 (S340).

In the above, the clock may be generated by replicating the period information previously detected by the receiver 300.

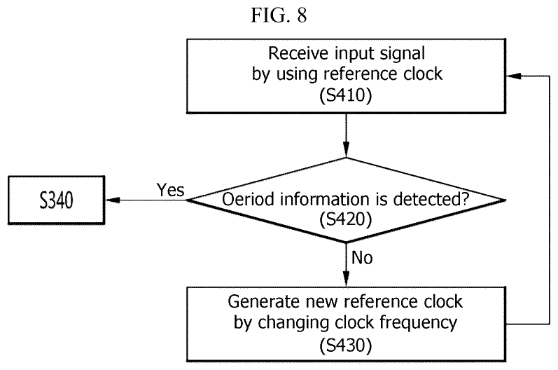

Next, referring to FIG. 8, the receiver 300 may receive an input signal by using a reference clock (S410).

The receiver 300 may determine whether period information is detected from the input signal by use of the reference clock (S420).

If periodic information is detected from the input signal as the result of determination at operation S420, the receiver 300 may proceed to operation S340 of FIG. 7.

On the other hand, if periodic information is not detected from the input signal as the result of determination at operation S420, the receiver 300 may generate a new reference clock by changing the clock value (S430).

Here, the new reference clock may refer to a reference clock having a clock value different from the reference clock used at operation S410.

As described above, the operation of FIG. 8 may be repeated m times (where m is a natural number) until an optimal reference clock is found.

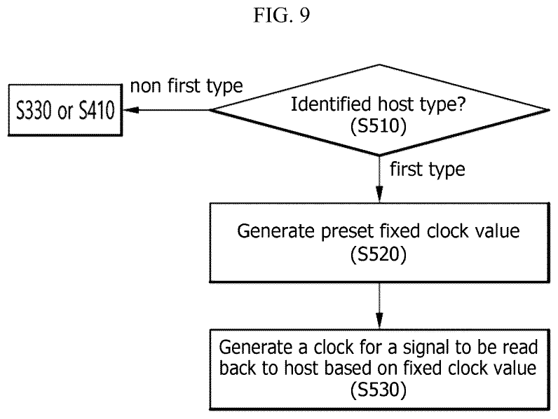

Finally, FIG. 9 may describe the operation of the receiver 300 when the fixed clock generator 345 is used instead of the automatic frequency detector 340, like the configuration block of the receiver 300 illustrated in FIG. 4. 4. However, this may be modified and applied to other aspects as well.

The receiver 300 may extract type information of the host 200 or identify the type of the host 200 based on the input signal filtered by the signal processing part 320.

The receiver 300 may check the identified host type (S510).

If the host type determined at operation S510 is not a first type, the receiver 300 may proceed to operation S330 of FIG. 7 or operation S410 of FIG. 8.

On the other hand, if the host type determined at operation S510 is the first type, the receiver 300 may generate a preset fixed clock value (S520). In this case, the fixed clock generator 345 may be used, for example.

The receiver 300 may then generate a clock for a signal to be read back to the host 200 based on the fixed clock value (S530).

In FIG. 9, the first type host may refer to, for example, a host that communicates by using a frequency agreed upon in advance between the host and the receiver.

Alternatively, the first type host may refer to a host that transmits a signal to the receiver in a specific frequency band predefined by the host.

Referring to FIG. 3 and/or FIG. 4, the processing process of the receiver 300 checking the frequency transmitted from the host 200 and correcting the frequency to read back it may be described as follows.

In the present disclosure, the frequency to be corrected or read back may represent a specific frequency, but may also represent a frequency range.

In the above, the specific frequency may indicate, for example, the frequency used in the fixed clock generator 345 illustrated in FIG. 4.

In the above, the frequency range may indicate, for example, a frequency or frequency range allowed by the host 200.

In the above, the frequency range may indicate, for example, a frequency or frequency range in which that the host 200 may perform signal processing.

In this way, according to the present disclosure, the receiver 300 checks the frequency transmitted from the host 200 and reads back the frequency with correction, thereby preventing the occurrence of unexpected events such as malfunctions that may occur due to a frequency difference between the host 200 and the receiver 300. This may ultimately ensure stable operation in both the host 200 and the receiver 300 during a signal processing process.

In the above, the operation of detecting period information may detect period information of the separated frequency components of the input signal by using a preset sampling frequency.

In the above, the preset sampling frequency may be different depending on the identified type of the host.

In the above, the operation of detecting period information may utilize a reference clock to detect period information of the input signal.

In the above, the reference clock may be different depending on the identified host type.

In the above, the reference clock may have a clock speed faster than the fastest frequency available to the host of the identified type.

In the above, the operation of detecting period information may be performed, for example, as follows.

A first reference clock having a first clock value may be transmitted, a determination may be made as to whether period information of the input signal is detected based on the first reference clock, and if the determination result shows that period information of the input signal is not detected, a second reference clock having a second clock value may be transmitted. In this case, the second clock value may be different from the first clock value and may be a large value.

Although the present disclosure has been described above with reference to aspects thereof, it will be readily understood by those skilled in the art that various modifications and changes may be made to the present disclosure without departing from the spirit and scope of the present disclosure as set forth in the following claims.

What is claimed is:

1. A receiver comprising:
a signal processing part configured to process an input signal of a host by using a first clock;
a frequency detector configured to detect frequency information of the input signal of the host based on the first clock and a sampling clock of the signal processing part; and
a controller configured to adaptively set a read back frequency of the receiver based on the detected frequency information of the input signal of the host.

2. The receiver of claim 1, further comprising a clock generator configured to generate a second clock for a signal to be transmitted to the host based on the adaptively set read back frequency of the receiver.

3. The receiver of claim 1, wherein the sampling clock is faster than the first clock of the signal processing part.

4. The receiver of claim 2, wherein the controller is configured to adaptively set the read back frequency in a manner that a ratio of a signal transmission frequency of the host and the read back frequency of the receiver is below a preset ratio.

5. The receiver of claim 1, wherein the controller is configured to identify a type of the host.

6. The receiver of claim 5, further comprising an internal oscillator configured to generate a clock determined according to the identified type of the host and input the clock to the frequency detector.

7. The receiver of claim 6, wherein the internal oscillator is configured to input a fastest clock frequency determined according to the identified type of the host to the frequency detector.

8. The receiver of claim 6, wherein in the case that the clock input to the frequency detector is slower than the sampling clock of the signal processing part, the internal oscillator is configured to newly generate a faster clock in sequence according to preset steps and input the same to the frequency detector.

9. The receiver of claim 2, further comprising a fixed clock value supplier configured to transfer a preset fixed clock value to the clock generator.

10. The receiver of claim 1, wherein the signal processing part is configured to separate data components and frequency components from the input signal of the host by using the first clock.

11. A display device comprising:
a display panel including a plurality of pixels;
a source driver configured to apply a data signal to the plurality of pixels;
a gate driver configured to apply a scan signal to the plurality of pixels; and
a timing controller configured to control the source driver and the gate driver,
wherein the source driver includes:
a signal processing part configured to process an input signal of the timing controller by using a first clock;
a frequency detector configured to detect frequency information of the input signal of the timing controller based on the first clock and a sampling clock of the signal processing part; and
a controller configured to adaptively set a read back frequency of the source driver based on the detected frequency information of the input signal of the timing controller.

12. The display device of claim 11, further comprising a clock generator configured to generate a second clock for a signal to be transferred to the timing controller based on the adaptively set read back frequency of the source driver.

13. The display device of claim 11, wherein the sampling clock is faster than the first clock of the signal processing part.

14. The display device of claim 12, wherein the controller is configured to adaptively set the read back frequency in a manner that a ratio of a signal transmission frequency of the timing controller and the read back frequency of the source driver is below a preset ratio.

15. The display device of claim 11, wherein the controller is configured to identify a type of the timing controller.

16. The display device of claim 15, further comprising an internal oscillator configured to generate a clock determined according to the identified type of the timing controller and input the clock to the frequency detector.

17. The display device of claim 16, wherein the internal oscillator is configured to input a fastest clock frequency determined according to the identified type of the timing controller to the frequency detector.

18. The display device of claim 16, wherein in the case that the clock input to the frequency detector is slower than the sampling clock of the signal processing part, the internal oscillator is configured to newly generate a faster clock in sequence according to preset steps and input the same to the frequency detector.

19. The display device of claim 12, further comprising a fixed clock value supplier configured to transfer a preset fixed clock value to the clock generator.

20. The display device of claim 11, wherein the signal processing part is configured to separate data components and frequency components from the input signal of the timing controller by using the first clock.
